(19) United States
(12) Patent Application Publication
(10) Pub. No.: US 2002/0101255 A1
(43) Pub. Date: Aug. 1, 2002

(54) Method and apparatus for a device under test fixture

(76) Inventors: Edward M. Nelson, Belton, TX (US); Raymond J. Hengel JR., Round Rock, TX (US)

Correspondence Address: Rick B. Yeager, 10805 Mellow Lane, Austin, TX, 78759, US

(21) Appl. No.: 09/772,233

(22) Filed: Jan. 29, 2001

(51) Int. Cl. G01R 31/02

(52) U.S. Cl. 324/755

(57) ABSTRACT

A test array is mountable on a test fixture having a set of test fixture sockets. Each of the test fixture sockets is configured to receive a device under test. The test array comprises a first heat sink having a position on the test array that corresponds to a first socket of the set. The test array also comprises a second heat sink having a position on the test array that corresponds to a second socket of the set. The test array further comprises a first set of heat sinks having a first heat sink height and a second set of heat sinks having a second heat sink height such that the difference in the heights compensates for differences in the warpage of the test fixture between the location of the first and second set of heat sinks.

### FIELD OF INVENTION

The present invention relates to electronic devices, and more particularly to testing of electronic devices.

### BACKGROUND

All electronic devices generate heat. The heat generated by an electronic device can alter the performance of the device, and in extreme cases can damage the electronic device.

The generation of heat is particularly problematic during testing, where many devices are placed in proximity and tested simultaneously. Modem manufacturing throughput requirements require testing many devices at once. Often, as many as 100 devices under test are placed in a test chamber and tested simultaneously.

The devices under test are placed in test fixtures, and the text fixtures stacked in a test chamber (known as an oven). Each test fixture typically has twenty-four test fixture sockets arranged in a 6-×-4 array of test fixture sockets within the test fixture, as shown in FIG. 1. Each socket is designed to receive and test one device at a time. Internally, each test socket has a large number of lead wire bond pads, configured to come in contact with ball array bond pads on any device placed within the socket.

A technician snaps each device into a test socket, where each bond pad on the device comes into physical contact with a bond pad on the test fixture socket. The devices are then operated at high speeds for long durations, while various tests are performed. During each test, the lead wires drive various electronic signals onto the device and receive similar signals from the device, and off-device evaluations are made to determine whether the device complies with manufacturing tolerances.

When driven in such large numbers in a confined space, the heat generated by such devices can far exceed the heat generated by any single device during actual operation of the end product, where fans and air vents can be used to pass air through the product to remove heat. The need for testing large numbers of devices in such close proximity makes it difficult to route sufficient air through the test fixtures to remove sufficient heat.

Removing heat from devices under test has generally required the use of heat sinks. A heat sink, comprising a metallic object with high thermal conductivity, is placed on each device. The heat sink is permanently attached onto a heat sink that is temporarily mounted onto the test fixture in such a way that the heat sink is in physical contact with the device under test within the test socket. Accordingly, after snapping each device into a test socket, the technician temporarily mounts a heat sink onto the test fixture socket. Cooling air flows through the test chamber, cooling the distal ends of each heat sink. The heat sinks draw heat away from each device and allow additional tests to be performed on the device.

While the use of heat sinks has proven advantageous for removing heat, mounting and removing the large number of heat sinks has been time consuming. Placing and removing a heat sink on each of twenty-four devices in a test fixture, and then doing so for each test fixture in a test chamber, introduces a significant time-consuming delay into the testing process.

### SUMMARY

The present invention includes a method and apparatus for a test array, configured to be mounted onto a test fixture. According to one aspect, the test array includes a number of heat sinks, located at various positions on the test array. In some embodiments, the number of heat sinks on the test array is quite large. When the test array is mounted onto a test fixture, each of the heat sinks on the test array comes into physical contact with a device under test. Moreover, in some embodiments, the heat sinks that are closer to the periphery of the test array have a shorter profile than other heat sinks that are further from it. When the test fixture is flexible, and bends as the test array is placed onto it, the greater heat sink profile height allows contact to be maintained, even for those devices under test that are furthest from periphery.

### BRIEF DESCRIPTION OF THE DRAWINGS

For a fuller understanding of the present invention, and the advantages thereof, reference should be made to the following detailed description of the taken in conjunction with the accompanying drawings in which:

FIG. 1 shows an overview of a burn-in oven with several test fixtures in a test chamber.

FIG. 2 shows a top view of a test array, having an array of heat sinks.

FIG. 3 shows a cross section of the test array of FIG. 2, observed near one edge of the test array, including a cut-away of a heat sink, depicting a heat sink and plurality of screws.

FIG. 4 shows a cross section of the heat sink of FIG. 3 in greater detail.

FIG. 5 shows a cross section of the cam mechanism of the heat sink of FIG. 3 in greater detail.

### DETAILED DESCRIPTION OF THE DRAWINGS

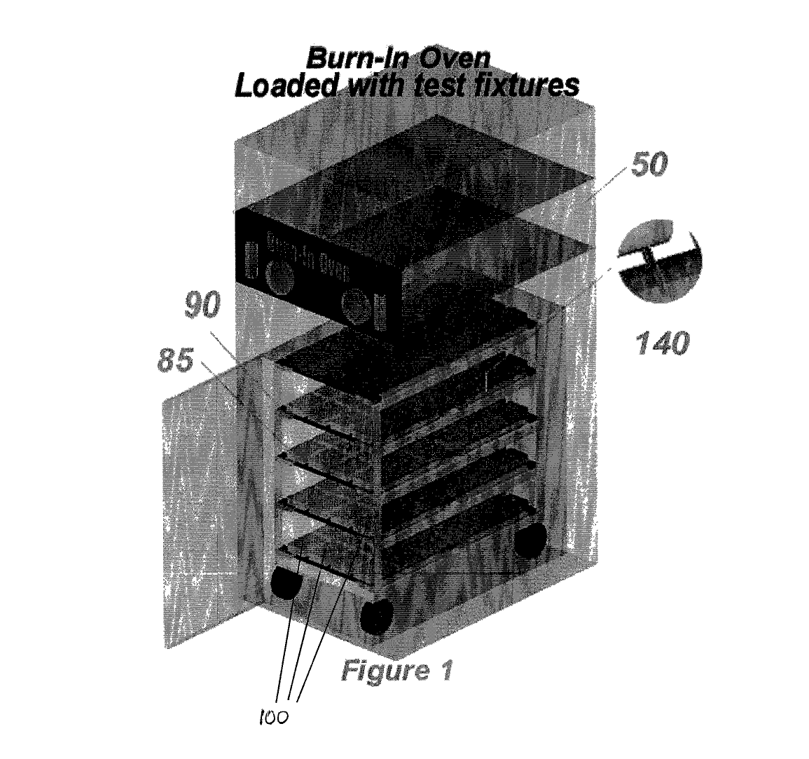

Referring now to FIG. 1, a typical fixture or burn-in board test fixture 90 has twenty-four test fixture sockets 100, arranged in an array of four rows and six columns. Each of the test fixture sockets 100 is configured to receive a digital logic device, such as a processor, and to provide input signals to the device, and to receive output signals from the device. Within the test fixture 90, additional signals route the input signals and output signals to an external test engine (not shown) and an external test analyzer (not shown). The external test engine initiates the test signals that are provided to the devices within the test fixture socket. The external test analyzer receives the output signals from the various devices and determines which devices pass and which devices fail the tests.

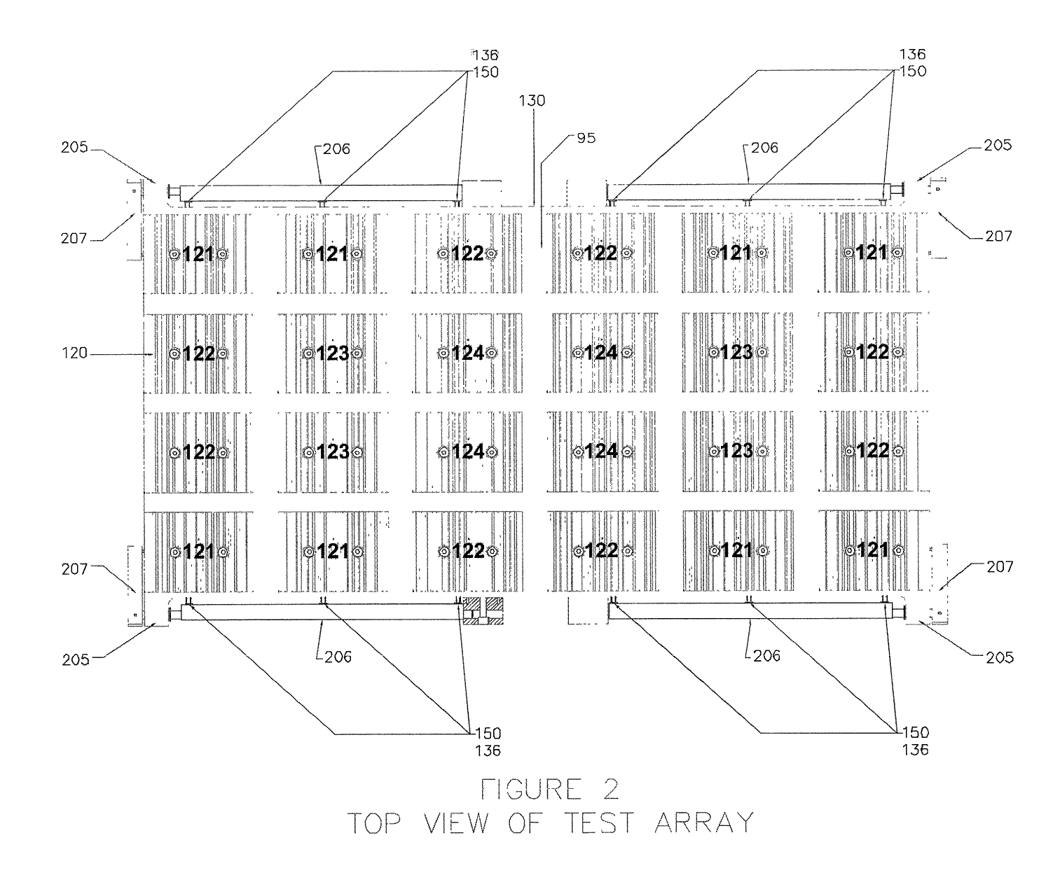

Along the edge of the test fixture 90, grooves 85 are provided to allow the test fixture to be placed in a test chamber 50. The test chamber, also known as a burn-in oven, routes input and output signals among various test fixtures 90. For example, a test chamber may allow the simultaneous testing of 240 digital logic devices, by providing space for ten test fixtures. Also, along the test fixture on the individual test fixture sockets 100, a series of small holes 140 is provided. The small holes 140 are designed to receive spring-mounted pins 150, described in reference to FIG. 2.

FIG. 2 shows a top view of a test array 95, having an array of twenty-four heat sinks 120. The test array 95 is configured to be mounted on the test fixture 90 before the test fixture 90 is placed into the test chamber 50.

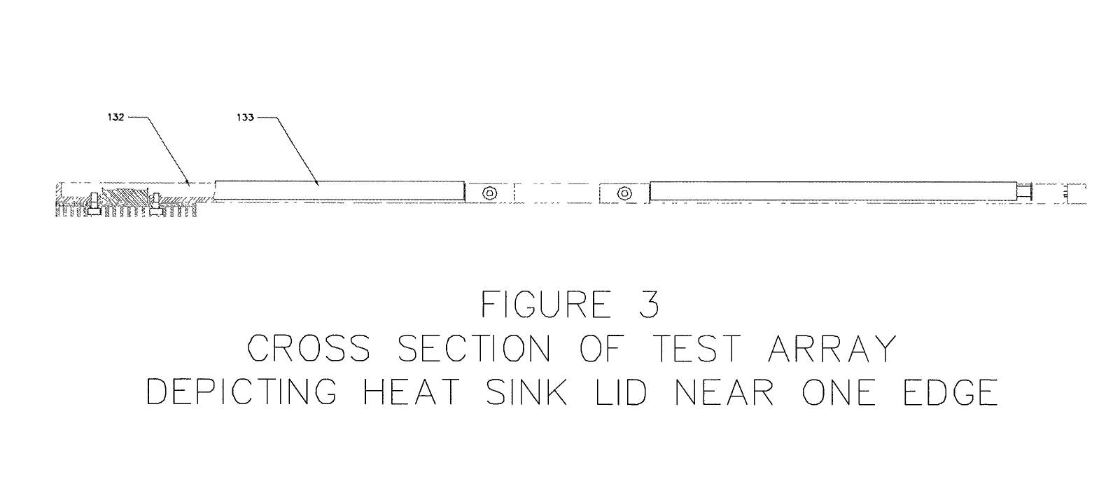

The test array 95 is a substantially planar structure, having twenty-four heat sinks 120 along its surface. However, the test array also has a flange lip 130 along each of its two longest edges, rising into the third dimension. The flange lips rise perpendicularly to the plane of the test array 95, and therefore perpendicular to the view in FIG. 3. The flange lips provide a mechanism for mounting the test array onto the test fixture. Each flange lip 130 has an inner surface 132, nearer to the heat sinks 120, and an outer surface 133.

Each of the flange lips 130 has a series of holes along its length. At each hole, a spring 136 and a pin 150 are provided on the outer surface 133 of the flange lip 130. The pin 150 is free to travel along its axis through the hole while pressure is applied to the head of the pin. The pin 150 travels parallel to the surface of the planar test array 95, perpendicular to the flange lip 130. When pressure is removed from the head of the pin 150, the spring 136 restores the pin 150 to the outer surface 133 of the flange lip 130.

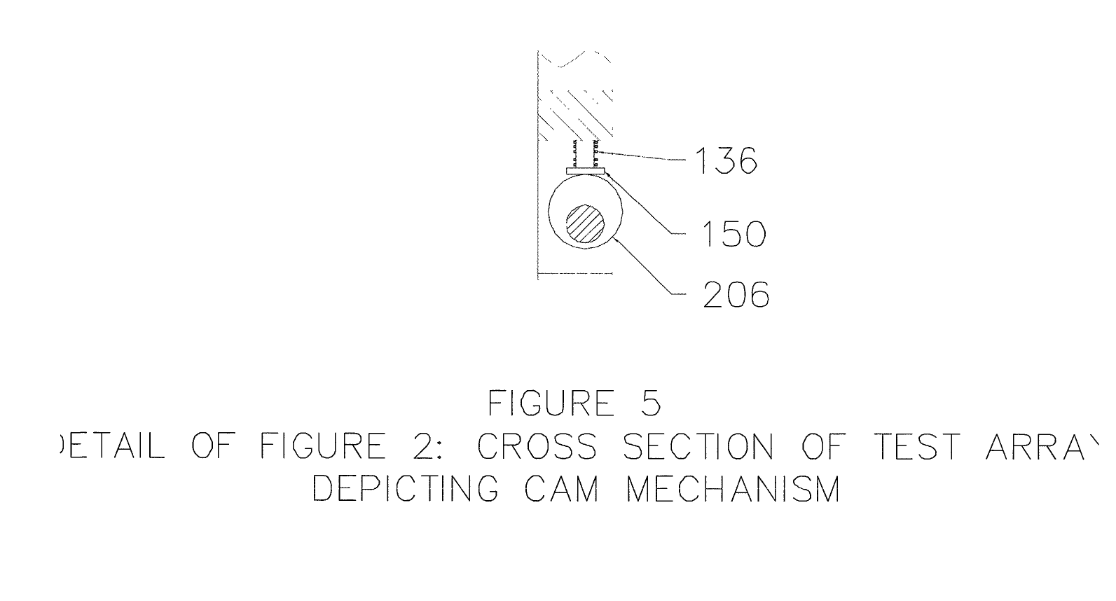

Referring now to FIG. 5, a detail of the spring 136, pin 150, and shaft 206 are shown in a cross section view of the cam mechanism.

As shown in FIG. 2, a cam mechanism 205 provides axial movement to the pins 150, which secure the test array 95 onto the test fixture 90. The cam mechanism 205 includes a shaft 206 and a handle 207. The handle 207 allows a technician to rotate a shaft 206 along an edge of the test array 95.

The shaft 206, however, does not have a circular cross section perpendicular to its axis; rather, the cross section of the shaft 206 perpendicular to its axis is preferably teardrop shaped.

Accordingly, as the shaft 206 is rotated about its axis, the distance between the surface of the shaft 206 and the flange lip 130 changes. The entire cam mechanism 205 is mounted on the test array 95 to operate in conjunction with the spring-mounted pins 150. When the handle 207 is in a first position, the distance between the shaft 206 and the flange lip 130 is maximized, and the spring mounted pins 150 retreat from the test fixture sockets 100. When the handle 207 is in a second position, the cam applies pressure to the heads of the spring-mounted pins 150, and the pins 150 are pressed axially.

The test array 95 of FIG. 2 is designed to be mounted onto the test fixture 90. When so mounted, the handle 207 can be moved from the first position to the second position allowing the screw-mounted pins to lock into the small holes 140 along the edge of the test fixture, and prevent movement of the test array 95 with respect to the test fixture.

The test array 95 of FIG. 2 includes twenty-four heat sinks which have four different thicknesses noted by the reference numbers 121 to 124 for this example. When the test array is mounted on the test fixture 90, each of the heat sinks is in physical and thermal contact with one of the devices in the test fixture sockets 100 of the test fixture 90. When the devices are tested while the test array is so mounted, the heat sinks are able to draw heat away from the devices.

As can be seen from reference to FIG. 2, the test array 95 so described allows the placement of twenty-four heat sinks 121-124 onto the surface of twenty-four digital logic devices much more quickly and easily. Instead of placing twenty-four separate heat sinks onto the test fixture 90, a technician can place all twenty-four heat sinks onto the test fixture in one step. Removing the heat sinks is also simplified. Instead of removing each of the twenty-four heat sinks one at a time from the test fixture, the technician can simply release the handle 207 and remove the entire test array 95 at once.

Also, the use of a handle 207 to “clamp” the heat sinks to the test fixture 90 is much easier and faster than the method previously used, i.e. using screws to attach each heat sink to the test fixture 90. Even when automatic screwdrivers or robotics are used to automate the insertion and removal of such screws, the ease and speed of the clamp described in reference to FIG. 2 is a vast improvement by comparison.

Generally, to ensure contact between the heat sinks and the electronic devices, pressure is applied to bring the test array 95 and the test fixture 90 closer together. The test array is pressed down onto the test fixture, and the handle 207 is moved to clamp the text array onto the test fixture. Since the clamping is realized only along the edges of the test array 95 and test fixture 90, it may appear that the test array 95 and/or test fixture 90 might bend or flex, increasing the distance between the test array and the test fixture near the center even while drawing the test array to the test fixture along the edges. It may even appear that such flexing may cause the heat sinks near the center of the test array to separate from the electronic devices near the center of the test fixture 90.

Indeed, there may be some flexing of the test array 95 and/or test fixture 90. However, according to another aspect of the present invention, the flexing does not cause the heat sinks to separate from the electronic devices. The reason the heat sinks can be maintained in contact with the electronic devices, despite the flexing of the test array and the test fixture, is that between the test array and each heat sink are springs, which allow movement of the heat sinks relative to the test array. Moreover, among the various heat sinks and test arrays, the pads are of differing thicknesses. The heat sinks mounted near the middle of the test array are thicker than the heat sinks near the edges of the test array.

The amount of variation among the heat sink thicknesses within a test array can be determined empirically. The variation in heat sink thicknesses within a test array may also be calculated, according to the rigidity of the test array and of the test fixture.

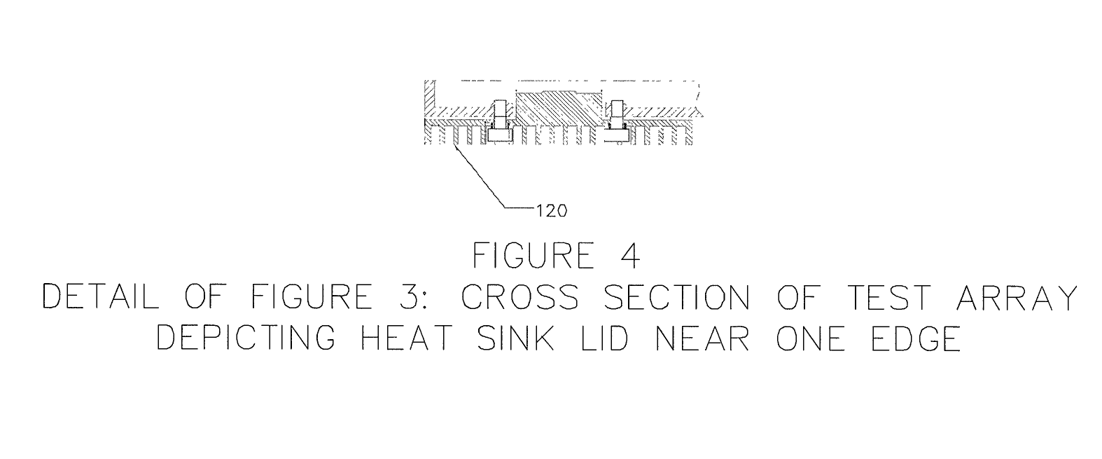

FIG. 4 shows a cross section of one heat sink 120 of FIG. 3 in greater detail. In this embodiment, the heat sink thickness can take on any of four values. The heat sink thicknesses depend on both the row and column in which the heat sink is situated. Like the test fixture sockets 100 of the test fixture 90, the heat sinks are organized into four rows and six columns.

Referring again to FIG. 2, the first and fourth rows of the test array 95 are adjacent to cam mechanisms 205 holding the test array 95 to the test fixture 90, and so that heat sinks are held to the electronic devices sufficiently. The second and third rows, however, display some distance between the test array and the test fixture, due to the flexing of the test array and the test fixture. Consequently, thicker heat sinks are required in the second and third rows than in the first and fourth rows.

Similarly, bowing is experienced in the other direction as well. Of the six columns of heat sinks, the test array and the test fixture are maintained most closely together in the first and sixth columns.

The heat sinks and electronic devices in the corners of the test array and test fixture, respectively, are adjacent to the cam mechanism 205 holding the test array 95 and the test fixture 90 together. Near the corners of the test array, therefore, the heat sinks may be thinnest, since each corner heat sink has only three adjacent heat sinks pushing the test array from the test fixture. In a first embodiment, such heat sinks 121 are 0.555 inches thick.

Away from the corners but along the edge of the test array, and adjacent to the cam mechanism 205, a slightly thicker heat sink 122 profile is necessary. Although these heat sinks and electronic devices are adjacent to the cam mechanism 205 holding the test array 95 to the test fixture 90, they are also surrounded by five adjacent heat sinks in the test array 95 and electronic devices in the test fixture 90 pushing the test array from the test fixture. In the first embodiment, such heat sinks 122 are 0.575 inches thick.

The slightly taller (0.575 inches thick) heat sink 122 profile is also necessary along the open edges of the test array 95, in the first and last column of the second and third rows.

Although removed from adjacency with the cam mechanism 205 holding the test array 95 to the test fixture 90, such pads are each surrounded by other test fixture sockets 100 in which heat sinks and electronic devices push the test array from the test fixture.

Still thicker pads are needed as the middle of the test array 95 is approached. In the second and fifth columns of the second and third rows, the bowing is such that a third heat sink thickness is needed. The third heat sink 123 thickness is greater than the first pad thickness found at the corners. The third heat sink thickness is even greater than the second heat sink thickness found in the heat sinks away from the corners but adjacent to the cam mechanism 205, and in the heat sink along the open edges of the test array 95 in the first and last column of the second and third rows. In the first embodiment, such heat sinks 123 are 0.595 inches thick.

Finally, a fourth pad thickness is needed near the middle of the test array 95, where bowing is most pronounced. The fourth heat sink thickness 124 is greatest of all in this embodiment, in the third and fourth columns of the second and third rows. Adding thickness to the heat sinks allows the heat sink to extend down into the socket and maintain physical contact with the electronic device, even when the test array 95 experiences significant bowing. In the first embodiment, such heat sinks 124 are 0.625 inches thick.

It should be appreciated by those skilled in the art that the specific embodiments disclosed above may be readily utilized as a basis for modifying or designing other techniques for carrying out the same purposes as the present invention, it should also be realized by those skilled in the art that such equivalent constructions do not depart from the spirit and scope of the present invention, as set forth in the appended claims.

What is claimed is:

1. A test fixture for testing a plurality of devices under test, the test fixture comprising:
a plurality of test fixture sockets, each socket accepting a device under test, such that the test fixture may be placed in a test chamber in order to electrically test the devices under test; and
a test fixture lid, the lid comprising
a frame,
a plurality of heat sink lids attached to the frame, such that a heat sink lid corresponds to each device under test, and
a mounting mechanism, such that the mounting mechanism temporarily attaches the test fixture lid to the test fixture, thereby bringing the heat sink lids in contact with the devices under test.

2. The test fixture of claim 1 wherein
a first heat sink lid has a first thickness; and
a second heat sink lid has a second thickness.

3. The test fixture of claim 2 wherein
a third heat sink lid has a third thickness.

4. The test fixture of claim 3 wherein
a fourth heat sink lid has a fourth thickness.

5. The test fixture of claim 1 wherein the mounting mechanism comprises:
a cam mechanism.

6. The test fixture of claim 5 wherein the cam mounting mechanism comprises:
a shaft having a cam-shaped cross section, and
a handle integral to the cam such that the handle may be turned to rotate the shaft, thereby causing the cam mechanism to push the test fixture lid onto the test fixture.

7. A test fixture for testing twenty-four devices under test, the test fixture comprising:
a plurality of test fixture sockets arranged in an array of four by six sockets, each socket accepting a device under test, such that the test fixture may be placed in a test chamber in order to electrically test the devices under test; and
a test fixture lid, the lid comprising
a frame having a plurality of openings such that each opening accepts a heat sink lid,
a plurality of heat sink lids attached to the frame, such that a heat sink lid corresponds to each device under test, and such that
a first set of heat sink lids has a first thickness,
a second set of heat sink lids has a second thickness,
a third set of heat sink lids has a third thickness,
a fourth set of heat sink lids has a fourth thickness,
a cam mounting mechanism, such that the cam mounting mechanism temporarily attaches the test fixture lid to the test fixture, thereby bringing the heat sink lids in contact with the devices under test.

8. A test fixture lid for a test fixture for testing a plurality of devices under test, the test fixture lid comprising:
a frame,
a plurality of first heat sink lids attached to the frame, such that each first heat sink lid corresponds to a device under test, and the first heat sink lids have a first thickness,
a plurality of second heat sink lids attached to the frame, such that each second heat sink lid corresponds to a device under test, and the second heat sink lids have a second thickness,
a mounting mechanism, such that the mounting mechanism temporarily attaches the test fixture lid to the test fixture, thereby bringing the first heat sink lids and second heat sink lids in contact with the devices under test.

10. A method of removing heat from a plurality of devices under test, the method comprising:
placing the devices under test in test fixture sockets on a test fixture board;
mounting heat sink lids on a test fixture lid;
temporarily attaching the test fixture lid to the test fixture board such that the heat sink lids contact the devices under test; and
placing the test fixture board in a test chamber.

11. The method of claim 10 further comprising
compensating for warpage of the test fixture so that heat sink lids contact devices under test after the test fixture lid is attached to the test fixture.

12. The method of claim 10 further comprising
mounting heat sink lids of various thicknesses on the test fixture lid.

13. The method of claim 12 further comprising
determining the thicknesses of the heat sink lids by determining the compensation required for the warpage of the test fixture after the test fixture lid is attached to the test fixture.
